(19) United States
(12) Patent Application Publication
(10) Pub. No.: US 2025/0204283 A1
(43) Pub. Date: Jun. 19, 2025

(54) LOW-VARIABILITY, HIGH-DENSITY DISC CELL WITH HORIZONTALLY ALIGNED ELECTRODES

(71) Applicant: INTERNATIONAL BUSINESS MACHINES CORPORATION, ARMONK, NY (US)

(72) Inventors: Timothy Mathew Philip, Albany, NY (US); Jin Ping Han, Yorktown Heights, NY (US); Ghazi Sarwat Syed, Kilchberg (CH); Kevin W. Brew, Niskayuna, NY (US); Ching-Tzu Chen, Ossining, NY (US); Benedikt Kersting, Lüdinghausen (DE); Vara Sudananda Prasad Jonnalagadda, Wallisellen (CH); Abu Sebastian, Adliswil (CH)

(21) Appl. No.: 18/540,847

(22) Filed: Dec. 14, 2023

(51) Int. Cl. H10N 70/20; H10B 63/00; H10N 70/00

(52) U.S. Cl. CPC H10N 70/231; H10B 63/80; H10N 70/021; H10N 70/063; H10N 70/066; H10N 70/068; H10N 70/841; H10N 70/8613

(57) ABSTRACT

A memory device includes a dielectric substrate and a first metal electrode contact layer coupled to the dielectric substrate. A metal heater element is disposed longitudinally on top of the first metal electrode contact. A first section of a layer of crystalline phase change material is positioned perpendicular to and in contact with an exposed first end of the longitudinally disposed metal heater element. A first section of a second metal electrode contact layer is positioned parallel to and spaced from, the first section of the layer of crystalline phase change material. A dielectric spacer is positioned between the layer of crystalline phase change material and the first section of the second metal electrode contact layer.

### BACKGROUND

### Technical Field

The present disclosure generally relates to semiconductor device fabrication, and more particularly, to a low-variability, high-density disc cell with horizontally aligned electrodes.

### Description of the Related Art

Phase-change memory (PCM) is an emerging non-volatile memory technology that has recently been commercialized as storage-class memory in a computer system. PCM is also being explored for non-von Neumann computing such as in-memory computing and neuromorphic computing. Phase change memory utilizes the orders of magnitude large difference between the resistivity of the amorphous and the crystalline phase in phase change materials. The phase change material in a PCM cell is located between two electrodes. Electrical currents are applied to switch the material (or at least a fraction of it that blocks the current path) repeatedly between the two phases.

Current PCM devices are called mushroom cells that use a phase-change material disposed between an enlarged switching contact area electrode (top electrode) and a small area contact bottom electrode (heater) element. The heater may be a via-based electrode that makes a small area contact with the phase change material. The electrical current that flows through the via-based heater electrode concentrates the heat just above the heater in the phase change material. Using a point-sized area contact for the heater electrode, it is common for current to jump straight from the heater electrode to the larger electrode unless the phase-change layer between the two electrodes is sufficiently thick. Alternatively, a disc or pancake cell can be made by forming contact points from the larger electrode are formed on the edges of the PCM away from the heater electrode. These cells enable the use of thinner PCM layers that have beneficial PCM properties like higher retention and lower programming current.

The top electrode is at a remote position relatively far away from the heater. The phase change material in a conventional PCM mushroom cell or cross-point pillar memory device may be approximately 30-100 nanometers thick, and the top electrode is placed directly on top of the phase change material. If the phase change material were made thinner in the conventional structure, with the contact electrode positioned in its typical location, the heat formed in the phase change material would be directly pulled out through the top electrode, which would negatively affect the ability of the crystalline material to effectively change states. Some designs such as the disc or pancake cells contact the top electrode from the edges forcing current to go sideways rather than just straight up, so that the heat gets retained.

### SUMMARY

According to an embodiment of the present disclosure, a memory device is disclosed. The memory device includes a dielectric substrate and a first metal electrode contact layer coupled to the dielectric substrate. A metal heater element is disposed longitudinally on top of the first metal electrode contact layer. A first section of a layer of crystalline phase change material is positioned perpendicular to and in contact with an exposed first end of the longitudinally disposed metal heater element. A first section of a second metal electrode contact layer is positioned parallel to and spaced from, the first section of the layer of crystalline phase change material. A dielectric spacer is positioned between the layer of crystalline phase change material and the first section of the second metal electrode contact layer.

According to another embodiment of the present disclosure, a memory device is disclosed. The memory device includes a dielectric substrate and a first metal electrode contact coupled to the dielectric substrate. A metal heater element extends linearly across and on top of a top surface of the first metal electrode contact. A second metal contact electrode is positioned above the metal heater element and above the first metal electrode contact. A layer of crystalline phase change material is positioned parallel to a side wall of the first metal electrode contact and perpendicular to a first end of the metal heater element. An electrode layer is coupled to the second metal contact electrode and positioned parallel to the layer of crystalline phase change material and perpendicular to the first end of the heater element.

According to another embodiment of the present disclosure, a method of manufacturing a memory device is provided. The method includes providing a substrate. A layer of insulation is formed on top of the substrate. A first electrode is formed in a pocket of the layer of insulation and on top of the substrate. A metal heater element is deposited linearly across a top surface of the layer of insulation and in contact with the first electrode. A second layer of insulation is formed on top of the metal and on top of the first layer of insulation. A layer of crystalline phase change material is deposited on at least a side wall of the first layer of insulation, a side wall of the second layer of insulation, and in contact with a first end of the metal heater element. A layer of spacer dielectric is conformally deposited over the layer of crystalline phase change material. A second electrode is formed over the layer of spacer dielectric. The second electrode is parallel to the layer of crystalline phase change material and perpendicular to the first end of the metal heater element.

The techniques described herein may be implemented in a number of ways. Example implementations are provided below with reference to the following figures.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1 is a cross-sectional view of a phase change memory device, according to an embodiment.

FIG. 2 is a perspective view of a heater section of the phase change memory device of FIG. 1, consistent with embodiments of the present disclosure.

FIG. 3 is a cross-sectional side view of an initial formation for a phase change memory device, consistent with an illustrative embodiment.

FIG. 4 is a cross-sectional side view of the formation of FIG. 3 after deposition of a thin metal heater element and a top dielectric, consistent with an illustrative embodiment.

FIG. 5 is a cross sectional side view of the device formation of FIG. 4 after a pocket is etched, consistent with an illustrative embodiment.

FIG. 6 is a cross-sectional side view of the formation of FIG. 5 after deposition of a phase change memory layer and deposition of a spacer dielectric, consistent with an illustrative embodiment.

FIG. 7 is a cross-sectional side view of the formation of FIG. 6 after deposition of an electrode metal layer, consistent with an illustrative embodiment.

FIG. 8 is a cross-sectional side view of the formation of FIG. 6 after an etching process, consistent with an illustrative embodiment.

FIG. 9 is a cross-sectional side view of the formation of FIG. 6 after forming a contact to the top electrode, consistent with an illustrative embodiment.

FIG. 10 is a cross-sectional side view of an initial formation for a phase change memory device, consistent with an illustrative embodiment.

FIG. 11 is a cross-sectional side view of the formation of FIG. 10 after deposition of a thin metal heater element and a top dielectric, consistent with an illustrative embodiment.

FIG. 12 is a cross sectional side view of the device formation of FIG. 11 after a pocket is etched, consistent with an illustrative embodiment.

FIG. 13 is a cross-sectional side view of the formation of FIG. 12 after deposition of a phase change memory layer and deposition of a spacer dielectric, consistent with an illustrative embodiment.

FIG. 14 is a cross-sectional side view of the formation of FIG. 13 after deposition of an electrode metal layer, consistent with an illustrative embodiment.

FIG. 15 is a cross-sectional side view of the formation of FIG. 14 after forming a contact to the top electrode, consistent with an illustrative embodiment.

FIG. 16 is a cross-sectional side view of an initial formation for a phase change memory device, consistent with an illustrative embodiment.

FIG. 17 is a cross-sectional side view of the formation of FIG. 16 after deposition of a thin metal heater element and a top dielectric, consistent with an illustrative embodiment.

FIG. 18 is a cross sectional side view of the device formation of FIG. 17 after a pocket is etched, consistent with an illustrative embodiment.

FIG. 19 is a cross-sectional side view of the formation of FIG. 18 after deposition of a phase change memory layer and deposition of a spacer dielectric, consistent with an illustrative embodiment.

FIG. 20 is a cross-sectional side view of the formation of FIG. 19 after deposition of an electrode metal layer, consistent with an illustrative embodiment.

FIG. 21 is a cross-sectional side view of the formation of FIG. 20 after etching a split into the top electrode metal layer, consistent with an illustrative embodiment.

FIG. 22 is a cross-sectional side view of the formation of FIG. 21 after forming contacts on both of the top electrodes, consistent with an illustrative embodiment.

### DETAILED DESCRIPTION

### Overview

In general, the subject technology provides a memory device that includes a phase change material (PCM) cell with a footprint that is smaller than the state of the art and with an improvement over the retention of current in the PCM layer. As may be appreciated, there exists some space between the heater element and the outer or top electrode contact of general PCM cell devices, which limits how small the PCM cell can be made. If the heater electrode contact is brought too close to the top electrode contact, the current may quickly conduct to the top electrode and the heat will have a more difficult time staying inside the phase change material. Generally, PCM cells position the electrode cooperating with the PCM layer on the top of the device. The thickness of the PCM layer and the span of the top electrode of conventional PCM cells create a relatively large footprint that limits the number of PCM cells that can be used in a circuit environment.

A device of the subject technology may reduce the footprint of the cell potentially is by turning the cell sideways. Where conventional PCM device use a small electrode for the heater electrode by printing a little via hole and filling the via metal, there exists a lot of variability in the uniformity (size and shape) of the via. When the via is small and then the footprint of the device is relatively large, the ability to scale the device or manufacture many devices in one package is limited.

According to an embodiment of the present disclosure, a memory device is disclosed. The memory device includes a dielectric substrate and a first metal electrode contact layer coupled to the dielectric substrate. A metal heater element is disposed longitudinally on top of the first metal electrode contact. A first section of a layer of crystalline phase change material is positioned perpendicular to and in contact with an exposed first end of the longitudinally disposed metal heater element. A first section of a second metal electrode contact layer is positioned parallel to and spaced from, the first section of the layer of crystalline phase change material. A dielectric spacer is positioned between the layer of crystalline phase change material and the first section of the second metal electrode contact layer.

As may be appreciated, the memory device structure uses a layer of a PCM that is perpendicular to a longitudinal heater element. Using longitudinal heater elements allows for a thinner profile (for example, 2 to 4 nanometers), so the overall cross-section is smaller. The cross-section of the heater element can be made much smaller than the state of the art, which reduces reset current. The longitudinal heater element is easier to pattern and thus provides improved uniformity over via patterning used by conventional heater elements. In addition, by forming the PCM layer and the second metal electrode contact layer perpendicular to the heater element (the PCM cell), which in some cases may be on a side of the device, the footprint of the PCM cell is reduced, resulting in a higher density of PCM devices that can be formed in a circuit environment. Also, the dielectric spacer between the PCM layer and the electrode prevents current from being drawn away from the PCM layer to the electrode too quickly.

According to an embodiment, which may be combined with any of the previous embodiments, the first section of the layer of crystalline phase change material is less than fifteen nanometers in thickness. A thinner layer of PCM also contributed to a smaller footprint of the PCM cell so that more PCM cells can be fit into the same area.

According to an embodiment, which may be combined with any of the previous embodiments, a second section of the layer of crystalline phase change material is positioned parallel to the metal heater element. A second section of the second metal electrode contact layer is positioned parallel to the metal heater element and on top of the second section of the layer of crystalline phase change material. By extending the PCM layer and the electrode over the top of the device, the area available for inducing an amorphous change in the PCM layer increases, which provides an opportunity for more programming.

According to an embodiment, which may be combined with one or more of the previous embodiments, a contact is positioned on top of the second section of the second metal electrode contact layer. The contact provides an element to access the PCM cell since in some embodiments, the PCM cell may be disposed on a side of the device which may not be available for direct contact.

According to an embodiment, which may be combined with one or more of the previous embodiments, a third section of the layer of crystalline phase change material is positioned perpendicular to and in contact with an exposed first end of the longitudinally disposed metal heater element. A third section of the second metal electrode contact layer is positioned parallel to and spaced from, the third section of the layer of crystalline phase change material. By wrapping the PCM layer around so that both ends of the heater element are contacted, the device now essentially has two PCM cells, which may provide for example, a contingency in case one of the PCM cells fails.

According to an embodiment, which may be combined with one or more of the previous embodiments, a contact is positioned on top of the second section of the second metal electrode contact layer. The contact provides an element to access the PCM cell since in some embodiments, the PCM cell(s) may be disposed on a side(s) of the device which may not be available for direct contact.

According to an embodiment, which may be combined with one or more of the previous embodiments, there is a first opening in the second section of the layer of crystalline phase change material and there is a second opening in the second section of the second metal electrode contact layer. The third section of the layer of crystalline phase change material is isolated from the first section of the layer of crystalline phase change material by the first opening in the second section of the layer of crystalline phase change material. The openings isolate the two sides of the device so that there are two PCM cells that can now be operated independently of each other.

According to an embodiment, which may be combined with one or more of the previous embodiments, a first contact is coupled to the first section of the second metal electrode contact layer. A second contact is coupled to the third section of the second metal electrode contact layer. The contacts provide independent access to the independently operating PCM cells.

According to another embodiment of the present disclosure, a memory device is disclosed. The memory device includes a dielectric substrate and a first metal electrode contact coupled to the dielectric substrate. A metal heater element extends linearly across and on top of a top surface of the first metal electrode contact. A second metal contact electrode is positioned above the metal heater element and above the first metal electrode contact. A layer of crystalline phase change material is positioned parallel to a side wall of the first metal electrode contact and perpendicular to a first end of the metal heater element. An electrode layer is coupled to the second metal contact electrode and positioned parallel to the layer of crystalline phase change material and perpendicular to the first end of the heater element.

As may be appreciated, the memory device structure uses a layer of PCM that is perpendicular to a longitudinal heater element. Using a linearly extending heater element allows for a thinner profile (for example, 2 to 4 nanometers), so the overall cross-section is smaller. The cross-section of the heater element can be made much smaller than the state of the art which reduces reset current. The linear heater element is easier to pattern and thus provides improved uniformity over via patterning used by conventional heater elements. In addition, by forming the PCM layer and the second metal electrode contact layer on side walls of the device and perpendicular to the heater element, the footprint of the PCM cell is reduced, resulting in a higher density of PCM devices that can be formed in a circuit environment.

According to an embodiment, which may be combined with one or more of the previous embodiments, the layer of crystalline phase change material is less than fifteen nanometers in thickness. A thinner PCM contributes to a smaller device footprint.

According to an embodiment, which may be combined with one or more of the previous embodiments, a section of insulation is positioned between the heater element and the second metal contact electrode. The layer of crystalline phase change material extends around the section of insulation, over a span of the heater element, and under the second metal contact electrode. By extending the PCM layer and the electrode over the top of the device, the area available for inducing an amorphous change in the PCM layer increases, which provides an opportunity for more programming.

According to an embodiment, which may be combined with one or more of the previous embodiments, the layer of crystalline phase change material extends down a side wall of the section of insulation in contact with a second end of the metal heater element. By wrapping the PCM layer around so that both ends of the heater element are contacted, the device now essentially has two PCM cells, which may provide, for example, a contingency in case one of the PCM cells fails.

According to an embodiment, which may be combined with one or more of the previous embodiments, the electrode layer is coupled to the second metal contact electrode and extends around three sides of the insulation. By wrapping the PCM layer around so that both ends of the heater element are contacted, the device now essentially has two PCM cells, which may provide for example, a contingency in case one of the PCM cells fails.

According to an embodiment, which may be combined with one or more of the previous embodiments, there is a split in the electrode layer coupled to the second metal contact electrode. The split isolates the two sides of the device so that there are two PCM cells that can now be operated independently of each other.

According to another embodiment of the present disclosure, a method of manufacturing a memory device is provided. The method includes providing a substrate. A layer of insulation is formed on top of the substrate. A first electrode is formed in a pocket of the layer of insulation and on top of the substrate. A metal heater element is deposited linearly across a top surface of the layer of insulation and in contact with the first electrode. A second layer of insulation is formed on top of the metal and on top of the first layer of insulation. A layer of crystalline phase change material is deposited on at least a side wall of the first layer of insulation, a side wall of the second layer of insulation, and in contact with a first end of the metal heater element. A layer of spacer dielectric is conformally deposited over the layer of crystalline phase change material. A second electrode is formed over the layer of spacer dielectric. The second electrode is parallel to the layer of crystalline phase change material and perpendicular to the first end of the metal heater element.

Forming a memory device with a PCM cell as disclosed provides a device with a smaller footprint. In addition, the dielectric spacer provides insulation so that current is retained by the PCM layer which prevents heat from being drawn out from the PCM layer to the electrode prematurely.

According to an embodiment, which may be combined with one or more of the previous embodiments, the layer of crystalline phase change material is less than fifteen nanometers in thickness. A thinner PCM contributes to a smaller device footprint.

According to an embodiment, which may be combined with one or more of the previous embodiments, the metal heater element is 2-10 nanometers in thickness. The smaller metal heater profile provides a smaller cross-section which reduces reset current in the device.

According to an embodiment, which may be combined with one or more of the previous embodiments, the layer of crystalline phase change material is deposited on a first side wall of the first layer of insulation, a top surface of the first layer of insulation, and a second side wall of the first layer of insulation, and in contact with a second end of metal heater element. By extending the PCM layer and the electrode over the top of the device, the area available for inducing an amorphous change in the PCM layer increases, which provides an opportunity for more programming. In addition, making contact with both ends of the heater element provides two PCM cells in the same device.

According to an embodiment, which may be combined with one or more of the previous embodiments, a metal contact is formed over the top surface of the first layer of insulation, in contact with the second electrode. The contact provides an element to access the PCM cell since in some embodiments, the PCM cell(s) may be disposed on a side(s) of the device which may not be available for direct contact.

According to an embodiment, which may be combined with one or more of the previous embodiments, the second electrode is formed over the first side wall of the first layer of insulation, the top surface of the first layer of insulation, the second side wall of the first layer of insulation, and in contact with the layer of crystalline phase change material. An opening is formed through the second electrode and through the layer of crystalline phase change material, isolating one section of the layer of crystalline phase change material from another section of the layer of crystalline phase change material. The opening in the electrode isolates the two parts of the device so that there are two PCM cells that can now be operated independently of each other.

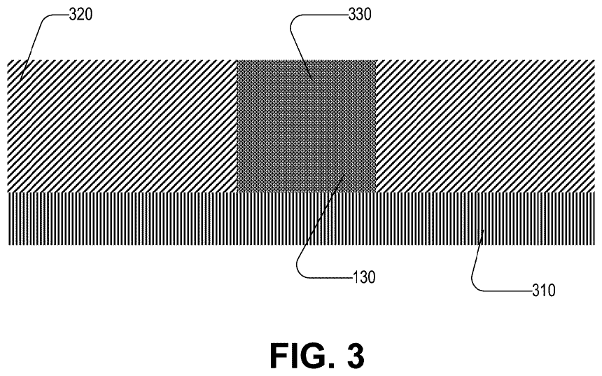

For the sake of brevity, conventional techniques related to semiconductor device and integrated circuit (IC) fabrication may or may not be described in detail herein (for example, the process leading up to the formation shown in FIGS. 3, 10, and 16 below). Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the direction of the Figures being described. Since components of embodiments of the disclosure can be positioned in a number of different directions, the directional terminology is used for purposes of illustration and is in no way limiting. Thus, it will be understood that the spatially relative terminology is intended to encompass different directions of the device in use or operation in addition to the direction depicted in the figures. For example, if the device in the figures is turned over, elements described as “below” or “beneath” other elements or features would then be oriented “above” the other elements or features. Thus, for example, the term “below” can encompass both an orientation that is above, as well as, below. Similarly, an element described as “on top of” of another element may mean either that the element is positioned above and is not necessarily in direct contact with the underlying element. The device may be otherwise oriented (rotated 90 degrees or viewed or referenced at other directions) and the spatially relative descriptors used herein should be interpreted accordingly.

As used herein, the terms “lateral”, “planar”, and “horizontal” describe an orientation parallel to a first surface of a chip or substrate. In the disclosure herein, the “first surface” may be the top layer of a semiconductor device where individual circuit devices are patterned in the semiconductor material.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together. The phrase “electrically connected” does not necessarily mean that the elements must be directly in physical contact together-intervening elements may be provided between the “connected” or “electrically connected” elements.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. Nor does describing an element as “first” or “second”, etc. necessarily mean that there is an order or priority to any of the elements. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope. It should be appreciated that the figures and/or drawings accompanying this disclosure are exemplary, non-limiting, and not necessarily drawn to scale.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

### Definitions

Phase Change Material (PCM): A material that by default is typically in a conductive crystalline state, and after exposure to a pulse of current on the order of nanoseconds to melt and quench the PCM, a portion of the PCM changes to a resistive amorphous state.

Heater Element: A metal element that conducts a current that is applied to a PCM.

Electrode: A metallic element that conducts positioned to transfer or receive a current.

A Top or Outer Electrode: An electrode positioned in cooperation with a PCM. The top electrode is typically on the opposite side of a PCM from a heater element.

### Example Device Structure

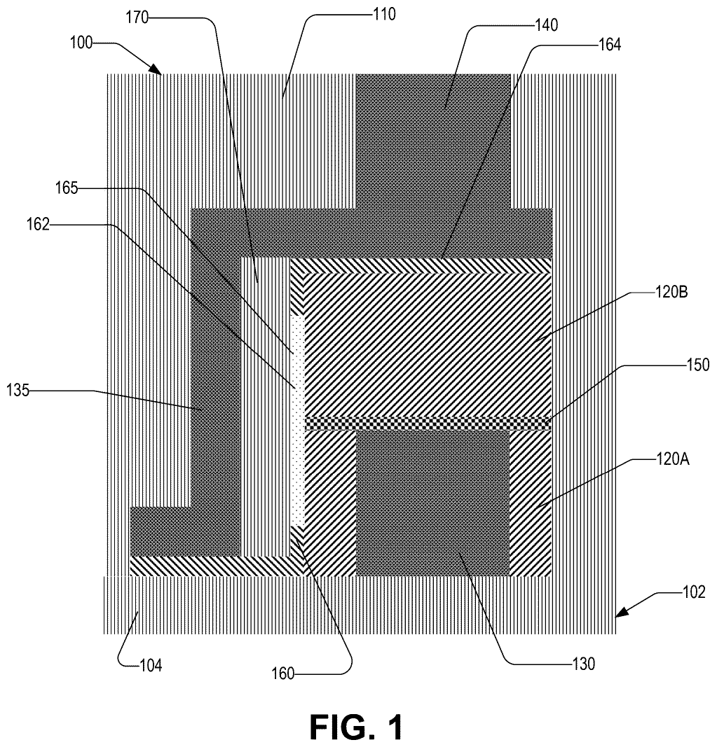

Referring now to FIG. 1, the subject disclosure provides a memory device 100 that is for example, a PCM cell. The memory device 100 generally includes a linearly disposed heater element 150 that spans transversely across the top surface of a first layer of insulation 120A and a first electrode 130. The heater element 150 may be for example, 80-200 nanometers long (20 nm from the edge of a 40 nm electrode contacting the heater element on either side up to 80 nm from the edge of the electrode to the heater element each way), and may have a profile that is approximately 2 to 6 nanometers thick. The heater element 150 is positioned perpendicular to a section of a PCM layer 160. The PCM layer 160 makes contact with a first end of the heater element 150.

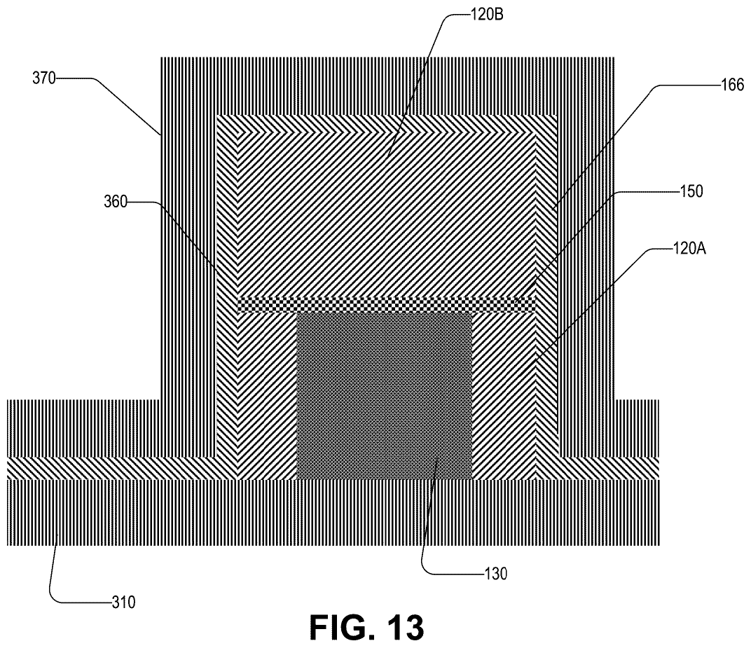

The memory device 100 may have the PCM layer 160 on at least a side wall of the first and second insulation layers 120A and 120B, referred to as the “first section 162 of the PCM layer 160”. Some embodiments may extend the PCM layer 160 to over the top of the second insulation layer 120B, which may be a “second (or top) section 164 of the PCM layer 160”. Some embodiments further extend the PCM layer 160 over the other side walls of the second insulation layer 120B into contact with a second end of the heater element 150 (which can be seen for example in FIG. 13). This section of the PCM layer 160 may be referred to as the “third section 166”. Some embodiments may extend the PCM layer 160 further over legs 104 of the dielectric substrate 102 that are not covered by the first insulation layer 120A or the first electrode 130.

The memory device 100 also includes a second electrode 135 positioned parallel to the first section 162 of the PCM layer 160 that is on the side walls of the insulation layers 120A and 120B. In some embodiments, the second electrode 135 may extend from the dielectric substrate 102, up to a level above the second section 164 of the PCM layer 160, and may span across the length of the PCM layer 160.

The memory device 100 may also include a dielectric spacer 170 that is situated between the first section 162 of the PCM layer 160 and the second electrode 135. In some embodiments, the second electrode 135 is a layer that extends over one end of the dielectric spacer 170. In some embodiments, the PCM layer 160 that is present on the legs 104 may cover the other end of the dielectric spacer 170.

Some embodiments of the memory device 100 includes one or more contacts 140 that are coupled to the second electrode 135. The contacts 140 provide access to the PCM layer 160, which may not be available in some circuits since some of the memory device elements are primarily positioned on the side and interior of the memory device 100. A dielectric 110 may cover exposed conductive parts of the memory device 100.

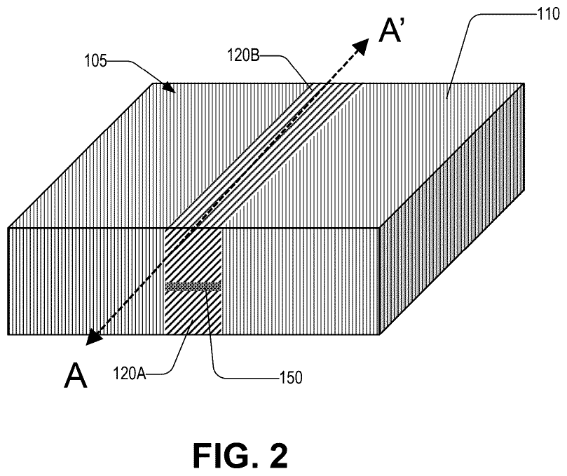

FIG. 2 shows a view of the heater assembly 105 in isolation. The heater assembly may include the heater element 150 which may span in a line longitudinally between the insulation layers 120A and 120B. FIG. 1 is a cross-section along the line A-A′. As can be seen in both the illustrations of FIG. 1 and FIG. 2, the PCM layer 160 has a relatively thin profile, which may be in the range of 2 to 15 nanometers thick. The cross-section of the contact area between the heater element 150 and the PCM layer 160 is relatively small at their intersection. When a high voltage pulse is applied to the heater element 150, the current generates heat to the PCM layer 160. Depending on the material used for the PCM layer 160, a section of the PCM layer 160 transforms into an amorphous material 165. As can be further seen by the illustration of FIG. 1, since the length of the PCM layer 160 may be extended all around the top and sides of the insulation layers 120A and 120B, the amount of amorphous material 165 available to program may be increased.

### Example Methodology of Manufacture

In the following, a process describes a general method of forming memory devices with one or more PCM cells that may be positioned on a side of the device. The fabrication of the devices described herein below can comprise multi-step sequences of, for example, photolithographic and/or chemical processing steps that facilitate gradual creation of electronic-based systems, devices, components, and/or circuits in a semiconducting and/or a superconducting device (e.g., an integrated circuit). For instance, memory device 100 can be fabricated on one or more substrates (e.g., a silicon (Si) substrates, and/or another substrate) by employing techniques including, but not limited to: photolithography, microlithography, nanolithography, nanoimprint lithography, photomasking techniques, patterning techniques, photoresist techniques (e.g., positive-tone photoresist, negative-tone photoresist, hybrid-tone photoresist, and/or another photoresist technique), etching techniques (e.g., reactive ion etching (RIE), dry etching, wet etching, ion beam etching, plasma etching, laser ablation, and/or another etching technique), evaporation techniques, sputtering techniques, plasma ashing techniques, thermal treatments (e.g., rapid thermal anneal, furnace anneals, thermal oxidation, and/or another thermal treatment), chemical vapor deposition (CVD), atomic layer deposition (ALD), physical vapor deposition (PVD), molecular beam epitaxy (MBE), electrochemical deposition (ECD), chemical-mechanical planarization (CMP), backgrinding techniques, and/or another technique for fabricating an integrated circuit.

In one embodiment, the base dielectric substrate 102 may be a bulk semiconductor substrate formed of, for example, silicon, or other types of semiconductor substrate materials that are commonly used in bulk semiconductor fabrication such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys.

Referring now to FIG. 3, an initial semiconductor device formation is shown. The initial formation may include a base substrate 310. A layer of insulation 320 may be formed over the substrate 310. A pocket may be formed in the insulation layer 320, into which a metal 330 is deposited (forming the first electrode 130).

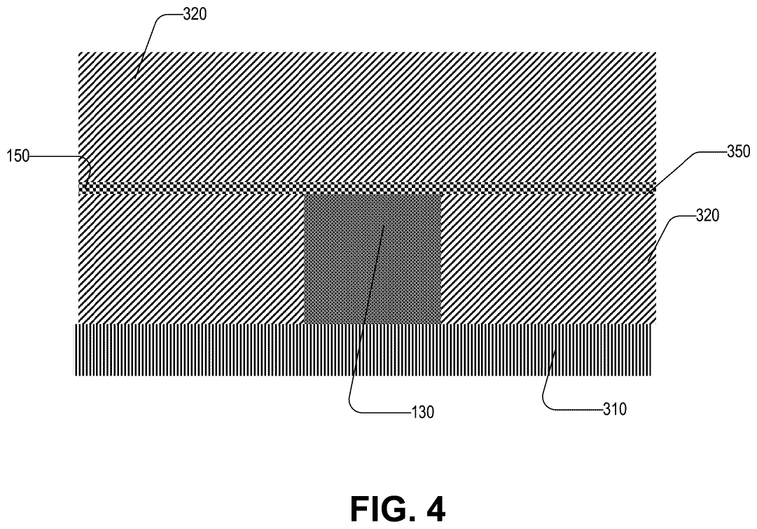

FIG. 4 shows a process of depositing a thin layer of metal 350 over the top of the layer of insulation 320 and the first electrode 130. The metal 350 may be deposited linearly across the span of the layer of insulation 320. The formation of the layer of metal 350 is the heater element 150 in the final device formation. Another layer of insulation 320 may be deposited over the layer of metal 350.

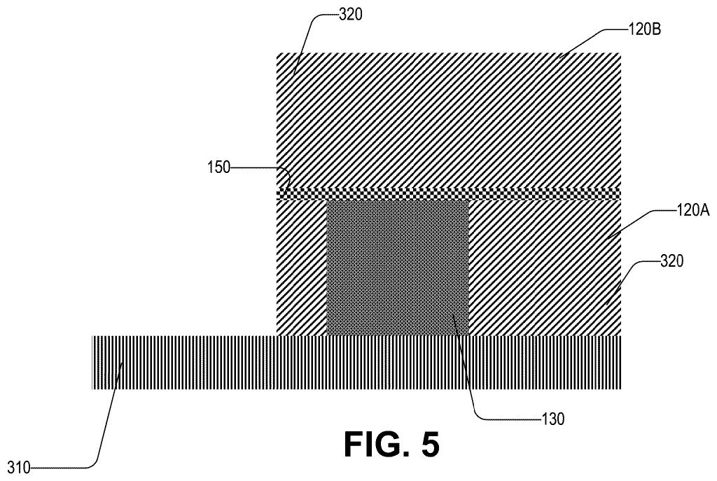

FIG. 5 shows a process of etching away some of the insulation layer 320 over the substrate 310 on one side of the formation. The area left vacated by etching will be used to form the PCM cell. The remaining insulation will be the first and second insulation layers 120A and 120B in the final device formation.

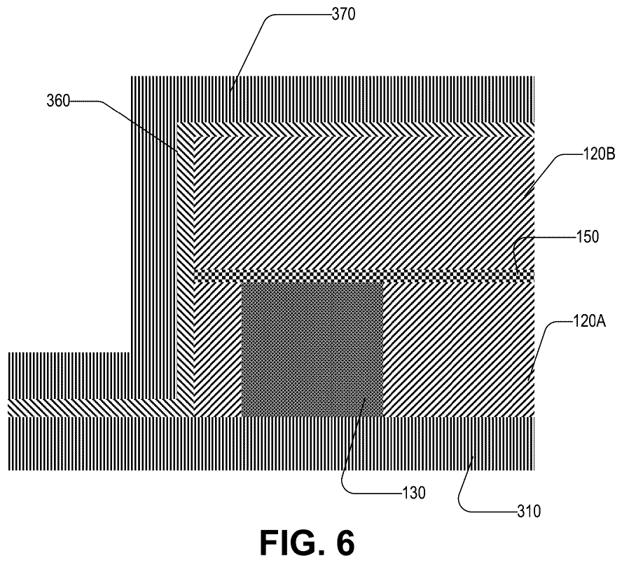

FIG. 6 shows a process of conformally depositing a layer of PCM 360 across the exposed areas of the substrate 310, up the sides of the insulation layers 120A and 120B (and in contact with an exposed end of the heater element 150), and across the top of the insulation layer 120B. Some embodiments may include conformally depositing a layer of spacer dielectric 370 over the top of the exposed areas of the layer of PCM 360.

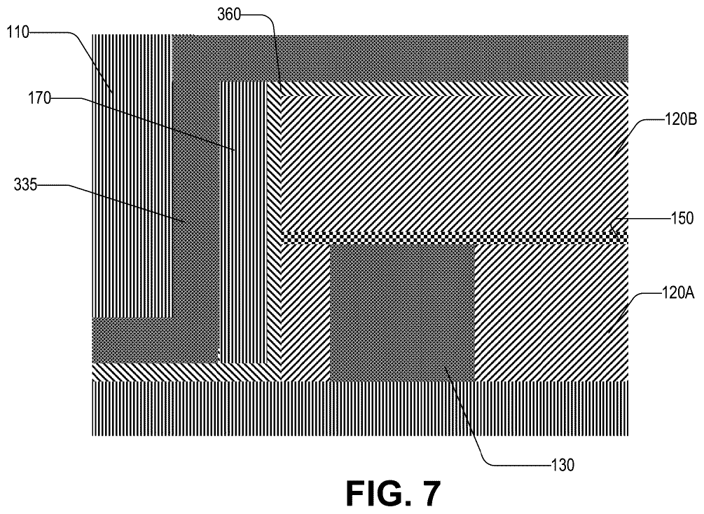

FIG. 7 shows a process after the layer of spacer dielectric 370 has been etched back from the top of the device and from above the layer of PCM 360 in the open area on the right side of the device. A layer of metal 335 may be deposited over the layer of PCM 360 and the layer of dielectric spacer 370. The layer of dielectric spacer 370 may now be enclosed by the layer of metal 335 and the layer of PCM 360, which forms the dielectric spacer 170 in the final device formation. The remaining open areas may be filled with a dielectric 110 and planarized.

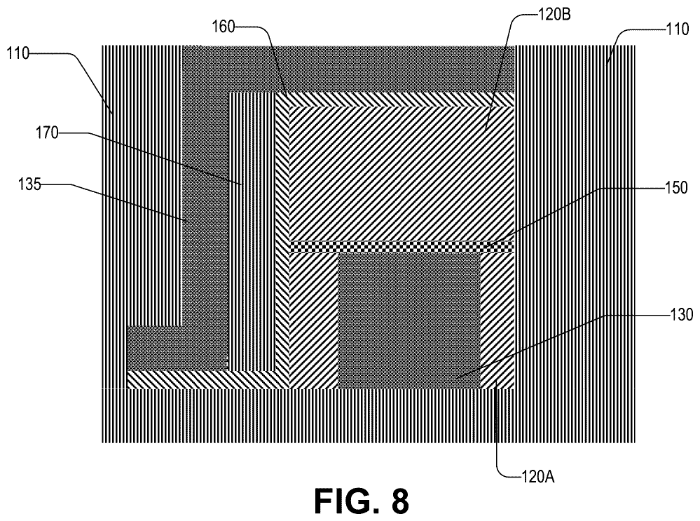

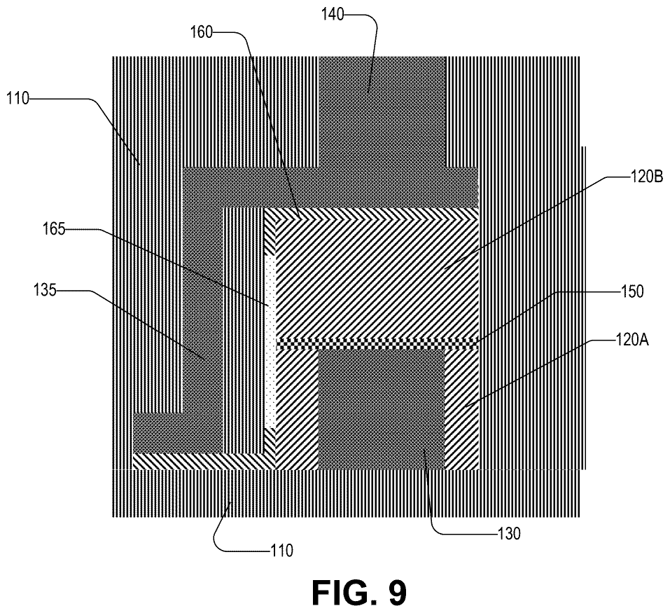

FIG. 8 shows a process of etching back the insulation layers 120A and 120B, the heater element 150, the layer of metal 335, and the layer of PCM 360, from the left side of the formation to a desired PCM cell size. The layer of metal 335, once encased by dielectric forms the second electrode 135. FIG. 9 shows a process after formation of a metal contact 140 is deposited in contact with the second electrode 135 on the top side of the final device formation.

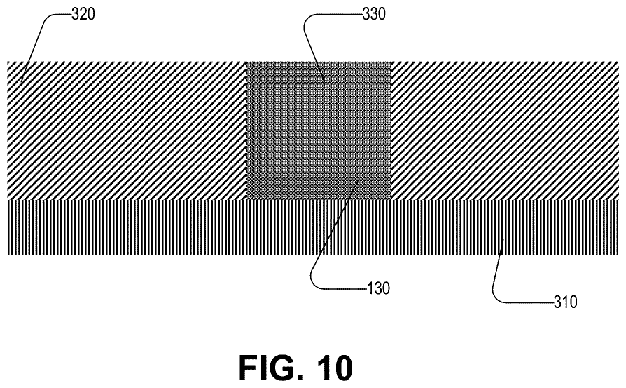

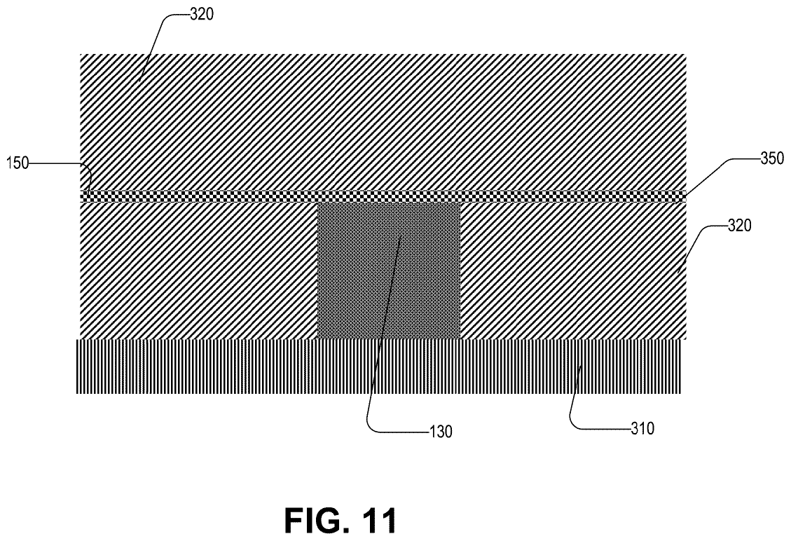

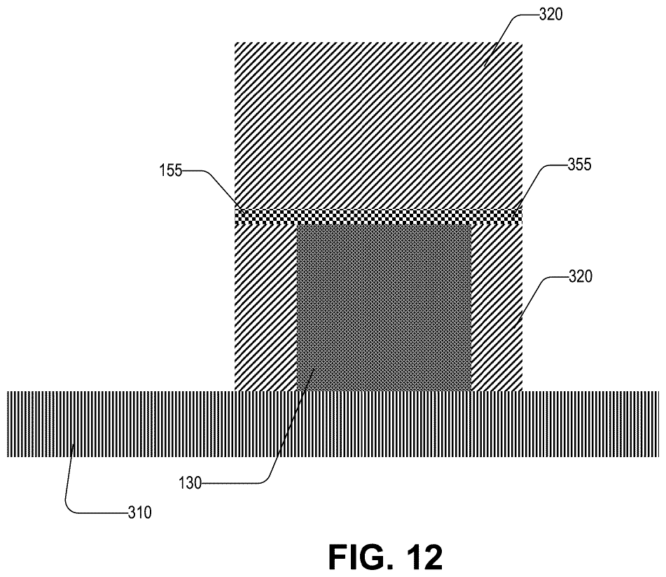

In the following process embodiment, the method of manufacturing provides a memory device that may have two instances of PCM cells in the same package. FIGS. 10 and 11 show initial formations for another process of manufacturing a memory device. FIGS. 10 and 11 show the same formations previously shown in FIGS. 3 and 4, so their description is not repeated for sake of brevity. FIG. 12 shows a process of similar to the process of FIG. 5 except that the etch back of the insulation layers 320 is performed on both sides of the formation.

In FIG. 13, the insulation layers 320 are encased and will now be referred to by their final device formation labels; insulation layers 120a and 120B. The process in FIG. 13 conformally deposits a layer of PCM 360 on both sides of the insulation layers 120A and 120 and over the top of insulation layer 120B. Some of the exposed areas of the supporting substrate 310 may be covered by the layer of PCM 360. A layer of spacer dielectric 370 may be conformally deposited over the layer of PCM 360.

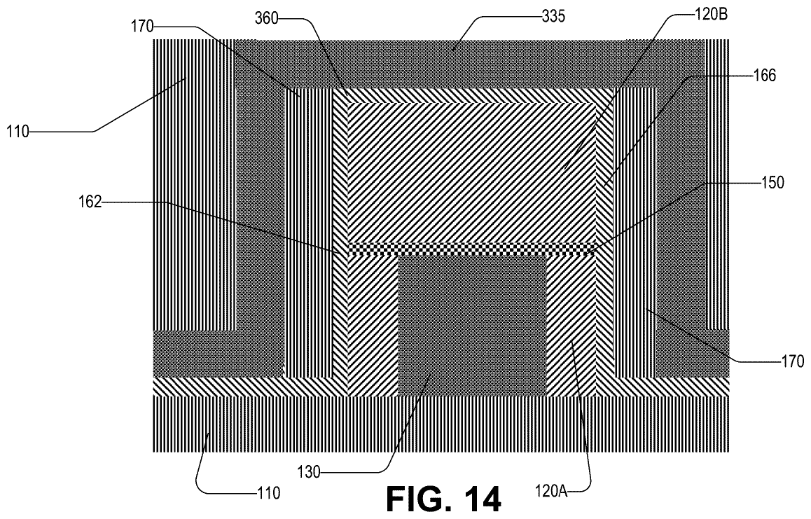

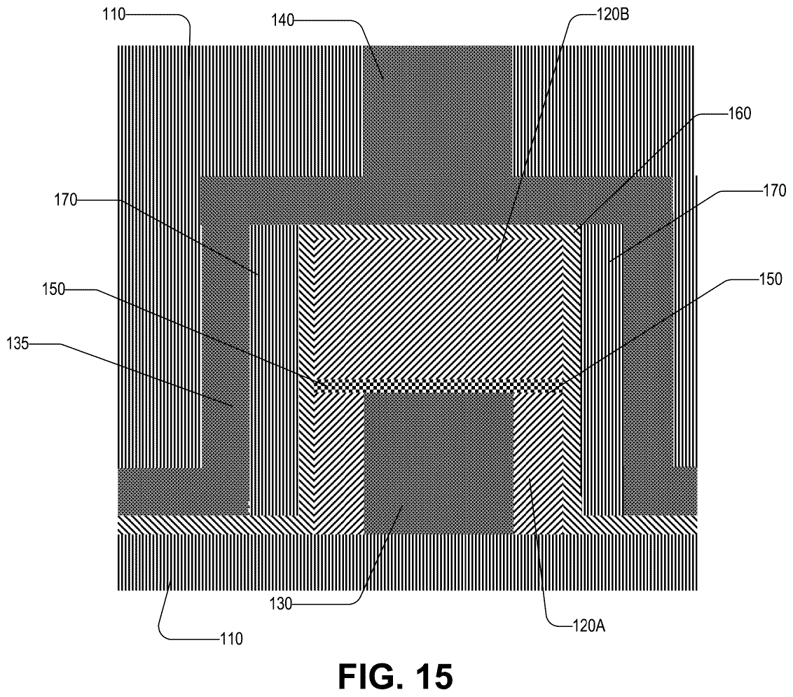

FIG. 14 shows a process after the layer of spacer dielectric 370 may be etched back everywhere except from the side walls of the insulation layers 120A and 120B and more accurately, from the sections of the layer of PCM 360 that will be the first section 162 and the third section 166. The remaining spacer dielectric material will be the dielectric spacers 170 in the final device formation. A layer of metal 335 may be deposited over the top of the layer of PCM 360 and the dielectric spacers 170. Dielectric 110 may fill in any open areas remaining on the formation. In FIG. 15, a metal contact 140 may be formed in contact with a top section of the metal layer 335, which becomes the second electrode 135. As can be seen in the final device formation of FIG. 15, the process provides two sections from which the heater element 150 may induce an amorphous reaction from the layer of PCM 160 on the sides of the device.

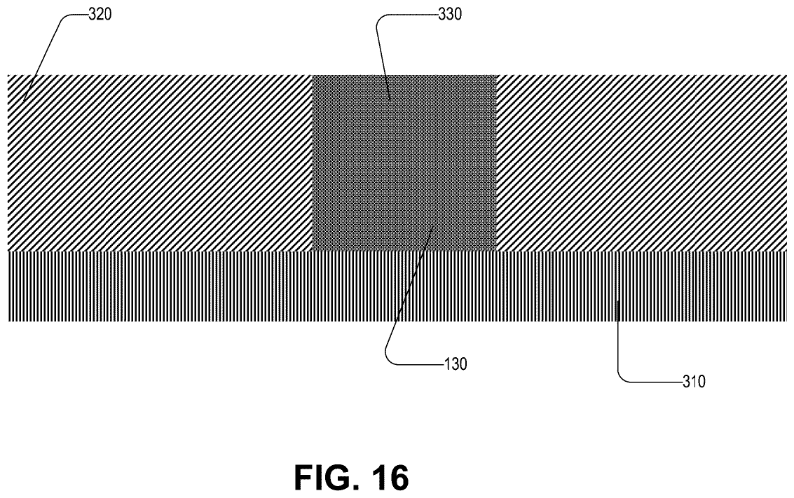

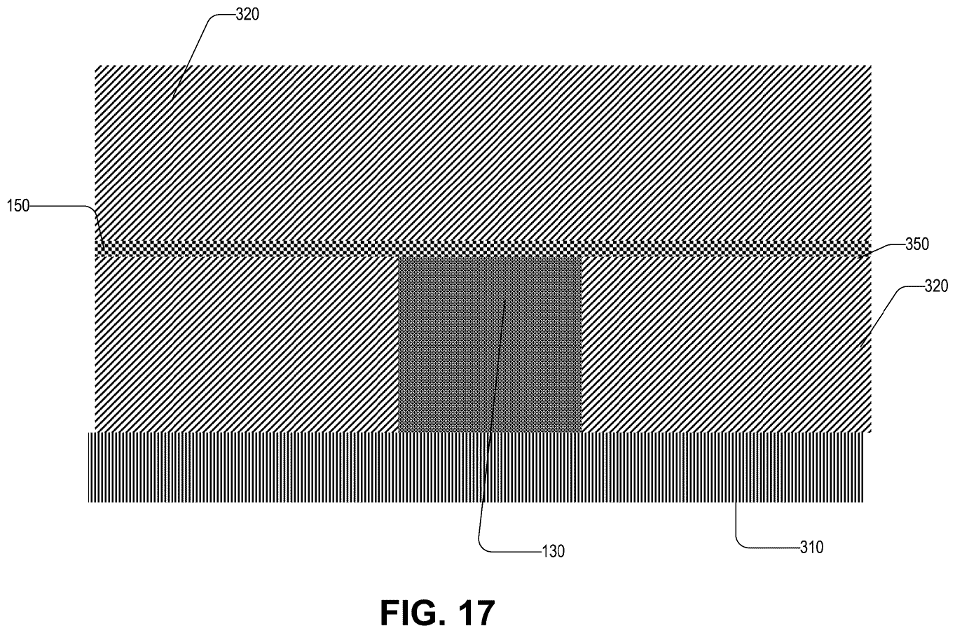

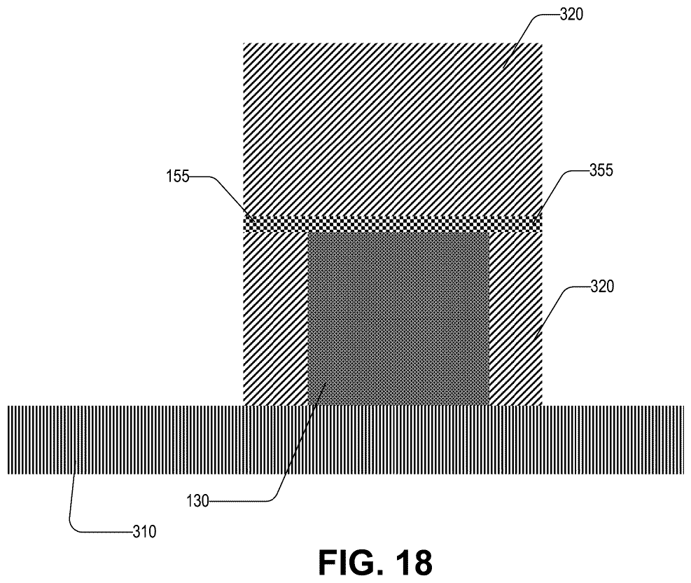

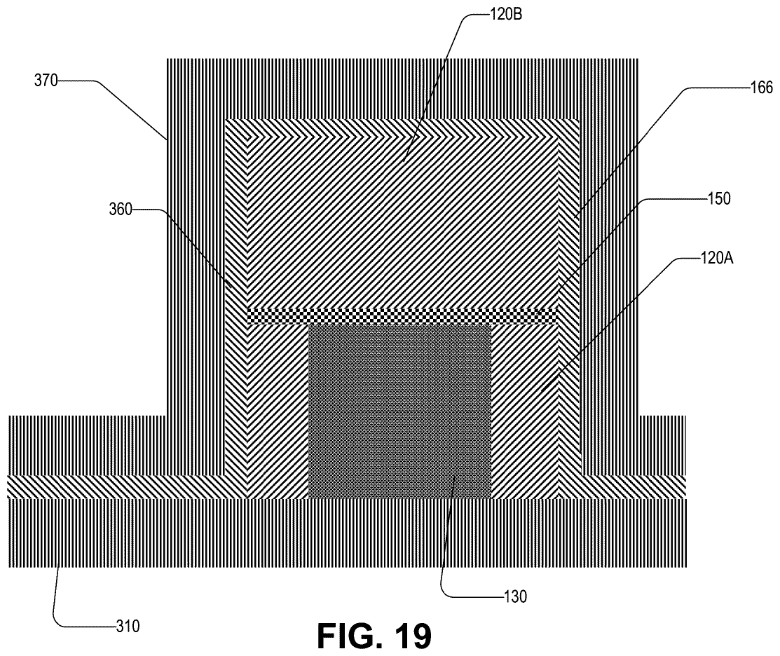

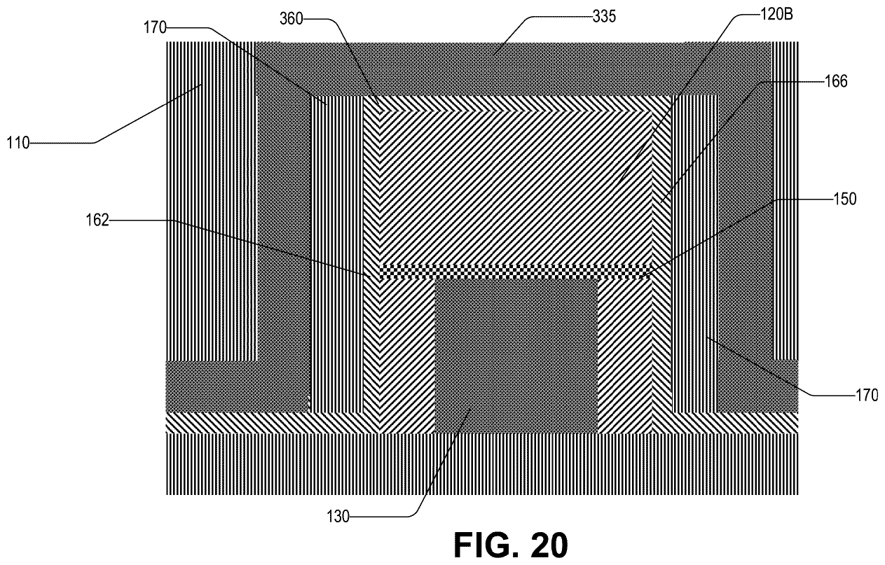

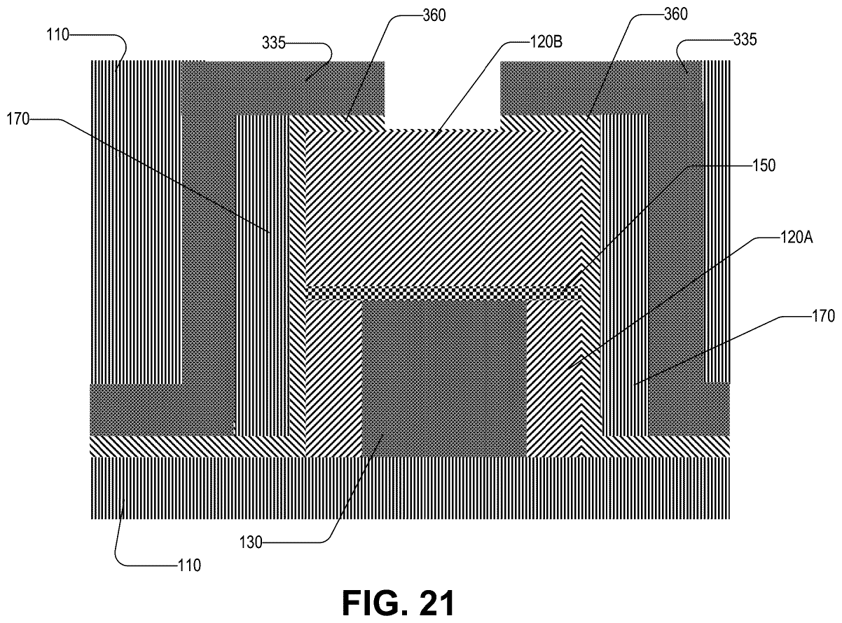

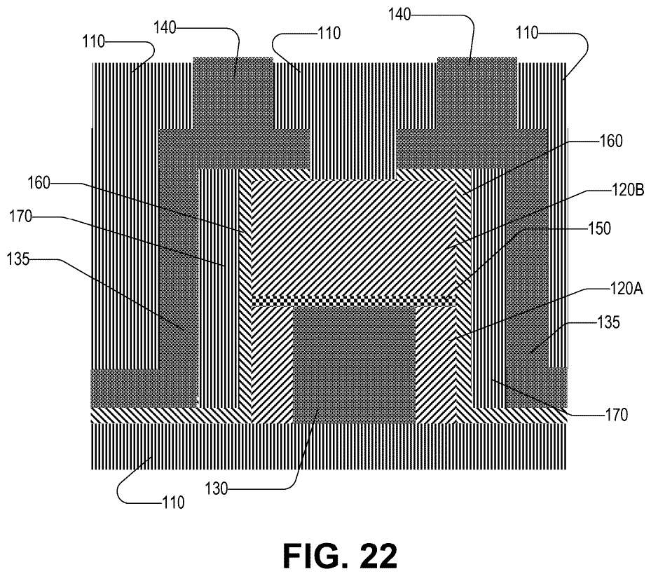

In the following process embodiment, the method of manufacturing provides a memory device that may have two instances of PCM cells that operate independently of one another in the same package. The formations shown in FIGS. 16-20 show the same formations shown in the previous embodiment in FIGS. 10-14, so their description is not repeated to avoid prolixity. FIG. 21 shows a process of forming an opening through the layer of metal 335 and through the layer of PCM 360 through the top of the formation down to the insulation layer 120B. By forming an opening through the layer of metal 335 and the layer of PCM 360, the device how has two PCM cells that are isolated from each other. As shown in FIG. 22, two different contacts 140 may be deposited in connection with respective second electrodes 135 on each side of the device. Each second electrode 135 cooperates with a set of the dielectric spacer 170 and a section of the PCM layer 160 that is also on the same side of the device. As can be appreciated, the process provide additional programming ability within the same package.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits, and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A memory device, comprising:
a dielectric substrate;
a first metal electrode contact layer coupled to the dielectric substrate;
a metal heater element disposed longitudinally on top of the first metal electrode contact layer;
a first section of a layer of crystalline phase change material positioned perpendicular to and in contact with an exposed first end of the longitudinally disposed metal heater element;
a first section of a second metal electrode contact layer positioned parallel to and spaced from, the first section of the layer of crystalline phase change material; and
a dielectric spacer positioned between the layer of crystalline phase change material and the first section of the second metal electrode contact layer.

2. The memory device of claim 1, wherein the first section of the layer of crystalline phase change material is less than fifteen nanometers in thickness.

3. The memory device of claim 1, further comprising:
a second section of the layer of crystalline phase change material positioned parallel to the metal heater element; and
a second section of the second metal electrode contact layer positioned parallel to the metal heater element and on top of the second section of the layer of crystalline phase change material.

4. The memory device of claim 3, further comprising a contact positioned on top of the second section of the second metal electrode contact layer.

5. The memory device of claim 3, further comprising:
a third section of the layer of crystalline phase change material positioned perpendicular to and in contact with an exposed first end of the longitudinally disposed metal heater element; and
a third section of the second metal electrode contact layer positioned parallel to and spaced from, the third section of the layer of crystalline phase change material.

6. The memory device of claim 5, further comprising a contact positioned on top of the second section of the second metal electrode contact layer.

7. The memory device of claim 5, further comprising:
a first opening in the second section of the layer of crystalline phase change material; and
a second opening in the second section of the second metal electrode contact layer, wherein the third section of the layer of crystalline phase change material is isolated from the first section of the layer of crystalline phase change material by the first opening in the second section of the layer of crystalline phase change material.

8. The memory device of claim 7, further comprising:
a first contact coupled to the first section of the second metal electrode contact layer; and
a second contact coupled to the third section of the second metal electrode contact layer.

9. A memory device, comprising:
a dielectric substrate;
a first metal electrode contact coupled to the dielectric substrate;
a metal heater element extending linearly across and on top of a top surface of the first metal electrode contact;
a second metal contact electrode positioned above the metal heater element and above the first metal electrode contact;
a layer of crystalline phase change material positioned parallel to a side wall of the first metal electrode contact and perpendicular to a first end of the metal heater element; and
an electrode layer coupled to the second metal contact electrode and positioned parallel to the layer of crystalline phase change material and perpendicular to the first end of the heater element.

10. The memory device of claim 9, wherein the layer of crystalline phase change material is less than fifteen nanometers in thickness.

11. The memory device of claim 9, further comprising a section of insulation positioned between the heater element and the second metal contact electrode, wherein the layer of crystalline phase change material extends around the section of insulation, over a span of the heater element, and under the second metal contact electrode.

12. The memory device of claim 11, wherein the layer of crystalline phase change material extends down a side wall of the section of insulation in contact with a second end of the metal heater element.

13. The memory device of claim 12, wherein the electrode layer coupled to the second metal contact electrode extends around three sides of the insulation.

14. The memory device of claim 13, further comprising a split in the electrode layer coupled to the second metal contact electrode.

15. A method of manufacturing a memory device, comprising:
providing a substrate;
forming a first layer of insulation on top of the substrate;
forming a first electrode in a pocket of the layer of insulation and on top of the substrate;
depositing a metal heater element linearly across a top surface of the first layer of insulation and in contact with the first electrode;
forming a second layer of insulation on top of the metal and on top of the first layer of insulation;
depositing a layer of crystalline phase change material on at least a side wall of the first layer of insulation, a side wall of the second layer of insulation, and in contact with a first end of the metal heater element;
conformally depositing a layer of spacer dielectric over the layer of crystalline phase change material; and
forming a second electrode over the layer of spacer dielectric, wherein the second electrode is parallel to the layer of crystalline phase change material and perpendicular to the first end of the metal heater element.

16. The method of claim 15, wherein the layer of crystalline phase change material is less than fifteen nanometers in thickness.

17. The method of claim 15, wherein the metal heater element is 2-10 nanometers in thickness.

18. The method of claim 15, wherein the layer of crystalline phase change material is deposited on a first side wall of the first layer of insulation, a top surface of the first layer of insulation, and a second side wall of the first layer of insulation, and in contact with a second end of metal heater element.

19. The method of claim 18, further comprising forming a metal contact over the top surface of the first layer of insulation, in contact with the second electrode.

20. The method of claim 18, wherein the second electrode is formed over the first side wall of the first layer of insulation, the top surface of the first layer of insulation, the second side wall of the first layer of insulation, and in contact with the layer of crystalline phase change material; and
the method further comprising forming an opening through the second electrode and through the layer of crystalline phase change material, isolating one section of the layer of crystalline phase change material from another section of the layer of crystalline phase change material.
